(19) United States
(12) Patent Application Publication
(10) Pub. No.: US 2026/0267378 A1
(43) Pub. Date: Sep. 10, 2026

(54) HINGE MECHANISM AND ELECTRONIC DEVICE

(71) Applicant: VIVO MOBILE COMMUNICATION CO., LTD., Dongguan (CN)

(72) Inventors: Yuanbiao LIANG, Dongguan (CN); Hailong ZHAO, Dongguan (CN)

(73) Assignee: VIVO MOBILE COMMUNICATION CO., LTD., Dongguan (CN)

(21) Appl. No.: 19/661,667

(22) Filed: Apr. 28, 2026

Related U.S. Application Data
(63) Continuation of application No. PCT/CN2024/132590, filed on Nov. 18, 2024.

(30) Foreign Application Priority Data
Nov. 23, 2023 (CN) 202311577250.7

(51) Int. Cl. G06F 1/16

(52) U.S. Cl. CPC G06F 1/1681; G06F 1/1652

(57) ABSTRACT

A hinge mechanism includes a base, a hinge bracket, a pressing member, and a swing arm. The hinge bracket is provided on the base. The hinge bracket is provided with an arc-shaped sliding slot. The swing arm is provided with an arc-shaped sliding portion. The arc-shaped sliding portion is in sliding fit with the arc-shaped sliding slot. The pressing member is located on a side of the arc-shaped sliding portion facing away from the hinge bracket, and the pressing member is connected to the hinge bracket.

### CROSS-REFERENCE TO RELATED APPLICATIONS

This application is a continuation of International Application No. PCT/CN2024/132590, filed Nov. 18, 2024, which claims priority to Chinese Patent Application No. 202311577250.7, filed Nov. 23, 2023. The entire contents of each of the above-referenced applications are expressly incorporated herein by reference.

### TECHNICAL FIELD

The present application pertains to the field of communication technologies, and specifically relates to a hinge mechanism and an electronic device.

### BACKGROUND

With the development of science and technology, the dependence of users on electronic devices is increasing. In order to improve the portability and use comfort of electronic devices, the application range of foldable electronic devices becomes increasingly wider.

In the related art, foldable electronic devices realizes folding and unfolding by means of a hinge mechanism. The hinge mechanism typically includes a base, a hinge bracket, and a swing arm. The hinge bracket is provided on the base, and the swing arm is rotatably connected to the hinge bracket, so that the unfolding and folding of the foldable electronic device are realized. The foldable electronic device typically further includes a display screen connected to the swing arm. When the swing arm rotates relative to the hinge bracket, the swing arm drives the display screen to deform, so that the folding and unfolding of the display screen are realized. However, in the folded state, the folded area of the display screen applies a force to the hinge bracket, and the hinge bracket is prone to deformation under stress. Then, the deformed portion of the hinge bracket acts on the swing arm, so that the swing arm is prone to misalignment relative to the hinge bracket, the swing arm is prone to locking during the rotation process, and the folding stability of the foldable electronic device is reduced.

### SUMMARY

The purpose of embodiments of the present application is to provide a hinge mechanism and an electronic device.

According to a first aspect, an embodiment of the present application provides a hinge mechanism, including a base, a hinge bracket, a pressing member, and a swing arm. The hinge bracket is provided on the base. The hinge bracket is provided with an arc-shaped sliding slot. The swing arm is provided with an arc-shaped sliding portion. The arc-shaped sliding portion is in sliding fit with the arc-shaped sliding slot. The pressing member is located on a side of the arc-shaped sliding portion facing away from the hinge bracket, and the pressing member is connected to the hinge bracket.

According to a second aspect, an embodiment of the present application further provides an electronic device, including a first device body, a second device body, and the hinge mechanism described above. The first device body is connected to the second device body through the hinge mechanism. During the relative rotation of the first device body and the second device body, the electronic device switches between an unfolded state and a folded state.

In the embodiments of the present application, the arc-shaped sliding portion slides relative to the arc-shaped sliding slot to realize the rotation of the swing arm relative to the hinge bracket. When the swing arm rotates to a position at which the hinge bracket is in the folded state, the display screen of the electronic device deforms and abuts against the hinge bracket, thereby applying a force to the hinge bracket. At the same time, the arc-shaped sliding portion of the swing arm abuts against the pressing member, and the arc-shaped sliding portion also applies a force to the pressing member. Since the pressing member is located on a side of the arc-shaped sliding portion facing away from the hinge bracket, the direction of the force borne by the hinge bracket and the direction of the force borne by the pressing member tend to be opposite, so that the force borne by the pressing member can at least partially offset the force borne by the hinge bracket, thereby making the overall structure formed by the hinge bracket and the pressing member in a relatively balanced state. Therefore, the arc-shaped sliding portion is not prone to deformation, and thus the swing arm is not prone to misalignment. The rotation process of the swing arm is smoother, which helps to improve the folding stability.

### BRIEF DESCRIPTION OF THE DRAWINGS

FIG. 1 is a partial structural schematic diagram of a hinge mechanism disclosed in an embodiment of the present application;

FIG. 2 is an exploded view of a hinge mechanism disclosed in an embodiment of the present application;

FIG. 3 is a structural schematic diagram of a base disclosed in an embodiment of the present application;

FIG. 4 is a top view of a partial structure of a hinge mechanism disclosed in an embodiment of the present application;

FIG. 5 is an enlarged view of portion S in FIG. 4;

FIG. 6 is a top view of a swing arm disclosed in an embodiment of the present application;

FIG. 7 is a side view of a swing arm disclosed in an embodiment of the present application;

FIG. 8 is a cross-sectional view taken along A-A in FIG. 6;

FIG. 9 is a structural schematic diagram of a pressing member disclosed in an embodiment of the present application;

FIG. 10 is a structural schematic diagram of a pressing member disclosed in an embodiment of the present application from another perspective;

FIG. 11 is a partial structural schematic diagram of a hinge mechanism in a folded state disclosed in an embodiment of the present application;

FIG. 12 is a cross-sectional view taken along B-B in FIG. 11; and

FIG. 13 is a structural schematic diagram of an electronic device disclosed in an embodiment of the present application.

### DETAILED DESCRIPTION OF EMBODIMENTS

The technical solutions in the embodiments of the present application will be described below with reference to the accompanying drawings in the embodiments of the present application. Obviously, the described embodiments are some embodiments of the present application, rather than all embodiments. Based on the embodiments in the present application, all other embodiments obtained by those of ordinary skill in the art without creative efforts fall within the scope of protection of the present application.

The terms “first”, “second”, and the like in the description and claims of the present application are used to distinguish similar objects and are not used to describe a specific order or sequence. It should be understood that the data so used can be interchanged under appropriate circumstances, so that the embodiments of the present application can be implemented in sequences other than those illustrated or described herein. The objects distinguished by “first”, “second”, and the like are usually of the same category and do not limit the number of objects. For example, a first object may be one or more. In addition, the “and/or” in the description and claims indicates at least one of the associated objects, and the character “/” generally indicates that the preceding and following related objects are in an “or” relationship.

The hinge mechanism and electronic device provided by the embodiments of the present application will be described in detail below with reference to the accompanying drawings through specific embodiments and application scenarios thereof.

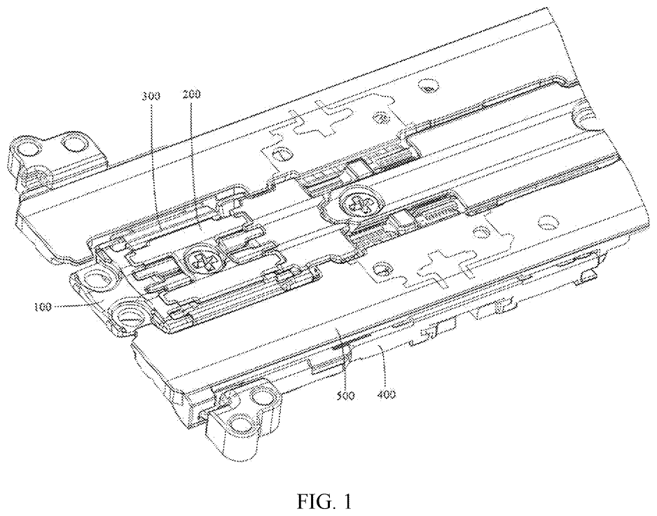

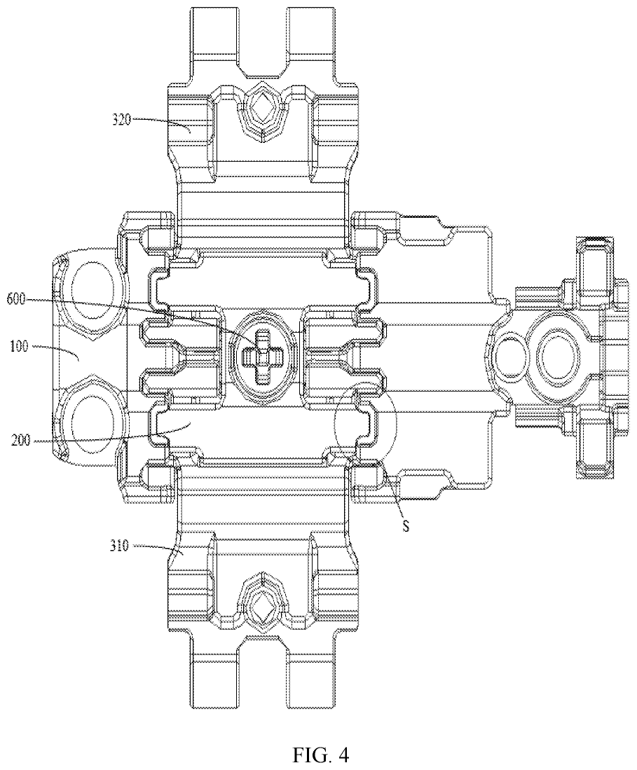

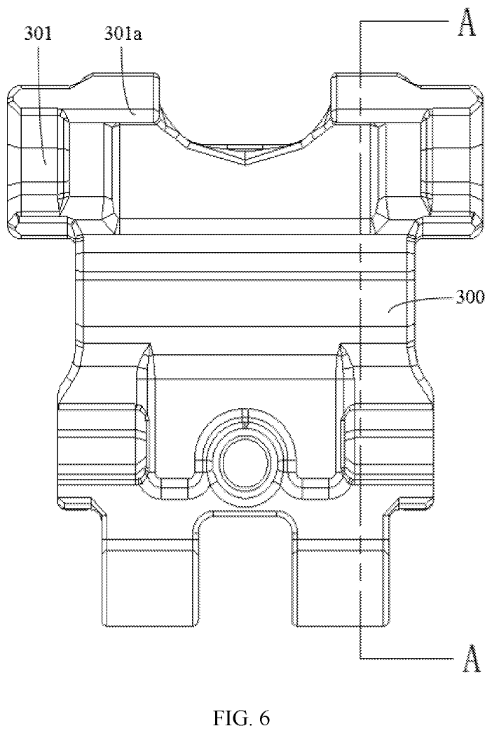

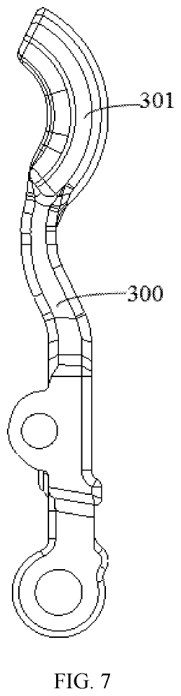

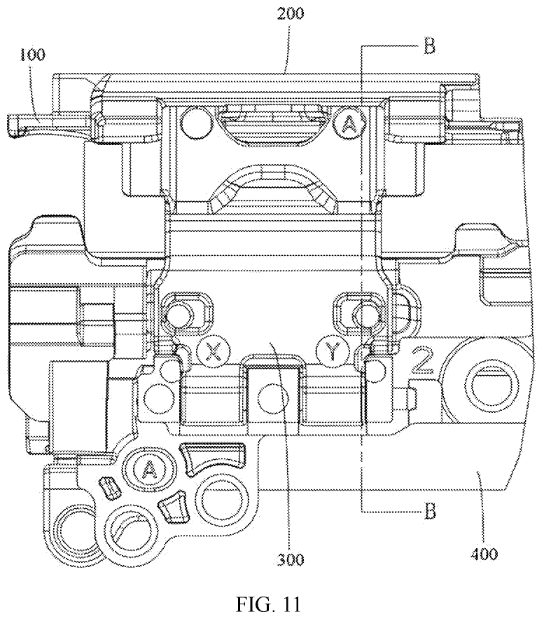

Referring to FIG. 1 to FIG. 13, the hinge mechanism disclosed in the embodiments of the present application includes a base 900, a hinge bracket 100, a pressing member 200, and a swing arm 300. The base 900 serves as an installation foundation for the hinge bracket 100, the pressing member 200, and the swing arm 300. The hinge bracket 100 is rotatably connected to the swing arm 300 to realize the rotation of the swing arm 300 relative to the hinge bracket 100. The pressing member 200 is configured to press the swing arm 300 to avoid misalignment of the swing arm 300 relative to the hinge bracket 100.

The hinge bracket 100 is provided on the base 900, and the hinge bracket 100 is connected to the base 900. The hinge bracket 100 is provided with an arc-shaped sliding slot 120. The swing arm 300 is provided with an arc-shaped sliding portion 301. The arc-shaped sliding portion 301 is in sliding fit with the arc-shaped sliding slot 120. In some embodiments, the arc-shaped sliding portion 301 and the arc-shaped sliding slot 120 are in sliding fit in the rotation direction of the swing arm 300 to realize the rotational connection between the hinge bracket 100 and the swing arm 300.

The pressing member 200 is located on a side of the arc-shaped sliding portion 301 facing away from the hinge bracket 100, and the pressing member 200 is connected to the hinge bracket 100. In some embodiments, the pressing member 200 and the hinge bracket 100 may be fixedly connected in a non-detachable manner such as welding, or may be fixedly connected in a detachable manner such as bolt connection. During the rotation of the swing arm 300 relative to the base 900, the pressing member 200 abuts against the arc-shaped sliding portion 301.

In the embodiments of the present application, when the swing arm 300 rotates to a position at which the hinge bracket 100 is in the folded state, the display screen 700 of the electronic device deforms and abuts against the hinge bracket 100, thereby applying a force to the hinge bracket 100. At the same time, the arc-shaped sliding portion 301 of the swing arm 300 abuts against the pressing member 200, and the arc-shaped sliding portion 301 also applies a force to the pressing member 200. Since the pressing member 200 is located on a side of the arc-shaped sliding portion 301 facing away from the hinge bracket 100, the direction of the force borne by the hinge bracket 100 and the direction of the force borne by the pressing member 200 tend to be opposite, so that the force borne by the pressing member 200 can at least partially offset the force borne by the hinge bracket 100, thereby making the overall structure formed by the hinge bracket 100 and the pressing member 200 in a relatively balanced state. Therefore, the arc-shaped sliding portion 301 is not prone to deformation, and thus the swing arm 300 is not prone to misalignment. The rotation process of the swing arm 300 is smoother, which helps to improve the folding stability.

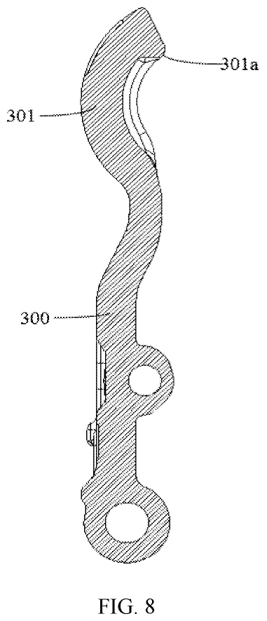

In some embodiments, as shown in FIG. 8, a first protrusion 301a is provided on a side of the arc-shaped sliding portion 301 facing the pressing member 200. When the hinge mechanism is in the folded state, the first protrusion 301a directly abuts against the pressing member 200. The embodiments of the present application do not specifically limit the structure of the first protrusion 301a, as long as it protrudes from the surface of the arc-shaped sliding portion 301. In this way, the arc-shaped sliding portion 301 is more easily abut against the pressing member 200 by means of the first protrusion 301a.

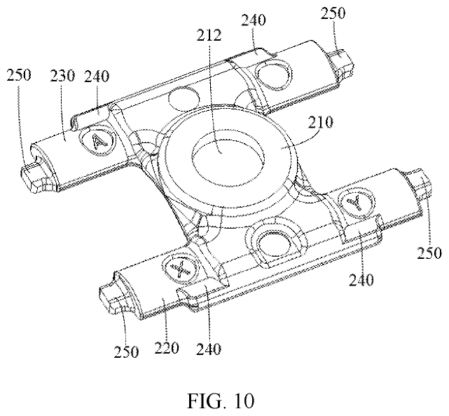

In another embodiment, as shown in FIG. 10, a second protrusion 240 is provided on a s ide of the pressing member 200 facing the arc-shaped sliding portion 301. When the hinge mechanism is in the folded state, the first protrusion 301a abuts against the second protrusion 240, that is, the arc-shaped sliding portion 301 abuts against the pressing member 200 through the first protrusion 301a and the second protrusion 240. The embodiments of the present application do not specifically limit the structure of the second protrusion 240, as long as it protrudes from the surface of the pressing member 200.

By adopting this embodiment, the pressing member 200 is further provided with the second protrusion 240, and the first protrusion 301a more easily abuts against the pressing member 200 through the second protrusion 240, which helps to increase the abutting force between the pressing member 200 and the arc-shaped sliding portion 301 during the folding process, even helps to maintain the overall structure formed by the hinge bracket 100 and the pressing member 200 in a relatively balanced state, and helps to further improve the folding stability.

In some embodiments, at least one of the first protrusion 301a and the second protrusion 240 is a block-shaped protrusion.

In another embodiment, at least one of the first protrusion 301a and the second protrusion 240 extends along a direction in which the rotation axis of the swing arm 300 is located, that is, at least one of the first protrusion 301a and the second protrusion 240 is a bar-shaped protrusion. In some embodiments, only the first protrusion 301a or the second protrusion 240 may extend along the direction in which the rotation axis of the swing arm 300 is located, or both the first protrusion 301a and the second protrusion 240 may extend in the direction in which the rotation axis of the swing arm 300 is located. During the folding process of the hinge mechanism, the swing arm 300 is prone to slippage in the direction in which its own rotation axis is located. Therefore, at least one of the first protrusion 301a and the second protrusion 240 is a bar-shaped protrusion, and the first protrusion 301a can abut against different positions of the second protrusion 240, so that the first protrusion 301a and the second protrusion 240 can continuously abut against each other, thereby ensuring that the arc-shaped sliding portion 301 continuously abuts against the pressing member 200.

In some embodiments, the number of the first protrusions 301a and the number of the second protrusions 240 are one for each.

In another embodiment, in the direction in which the rotation axis of the swing arm 300 is located, at least two first protrusions 301a are arranged on the swing arm 300 at intervals, at least two second protrusions 240 are arranged on the pressing member 200 at intervals, and the first protrusions 301a are in one-to-one correspondence with the second protrusions 240. In this way, by providing at least two groups of corresponding first protrusions 301a and second protrusions 240, different positions of the arc-shaped sliding portion 301 respectively abut against different positions of the pressing member 200, which helps to increase the abutting force between the arc-shaped sliding portion 301 and the pressing member 200, and also helps to improve the abutting stability between the arc-shaped sliding portion 301 and the pressing member 200.

In some embodiments, different positions of the pressing member 200 are detachably connected to the hinge bracket 100 through fasteners 600 respectively.

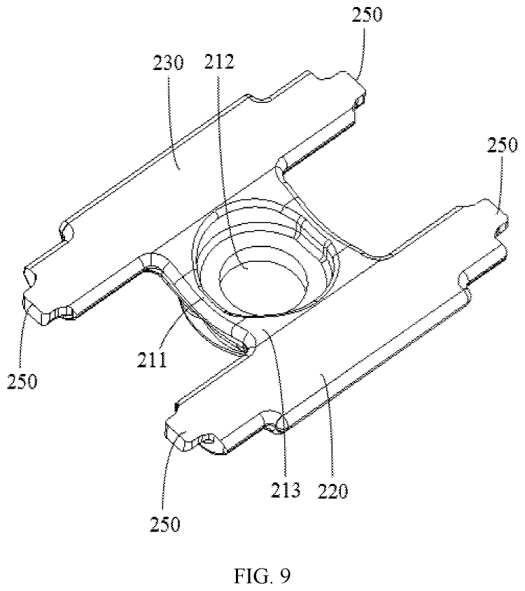

In another embodiment, the pressing member 200 includes a main body portion 210 and an extension portion that are connected to each other. The main body portion 210 is detachably connected to the hinge bracket 100 through a fastener 600. When the hinge mechanism is in the folded state, the extension portion abuts against the arc-shaped sliding portion 301. The fastener 600 may be a threaded fastener such as a screw or a bolt. In some embodiments, referring to FIG. 9, the main body portion 210 is provided with a connection hole 212. The hinge bracket 100 is provided with a threaded hole, and the fastener 600 passes through the connection hole 212 and is in threaded fit with the threaded hole. In some embodiments, the main body portion 210 and the extension portion may be an integral structure, or they may be a separate structure.

By adopting this embodiment, only the main body portion 210 of the pressing member 200 needs to be connected to the hinge bracket 100 through the fastener 600, which can maintain the overall stability of the pressing member 200, avoid the need to provide fasteners 600 at different positions of the pressing member 200 respectively, and prevent the use of a plurality of fasteners 600 connected to the hinge bracket 100 from leading to large space occupation, which helps to reduce the space occupation of the hinge mechanism, and thus helps to realize miniaturization of the electronic device.

In some embodiments, the number of the swing arms 300 and the number of the extension portions are one for each, and the arc-shaped sliding portion 301 of the swing arm 300 abuts against the extension portion.

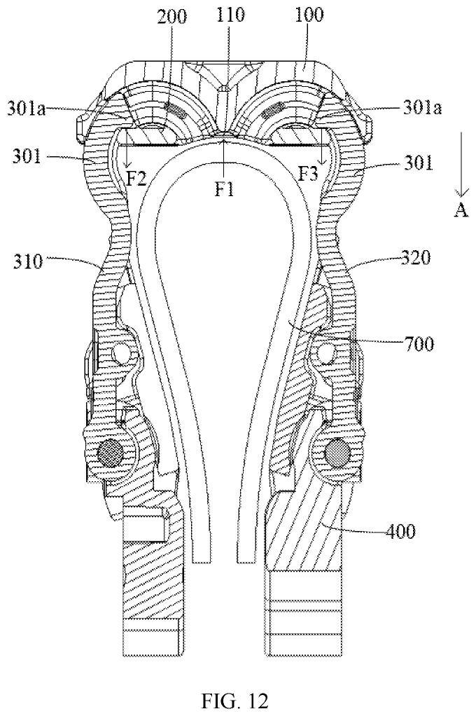

In another embodiment, referring to FIG. 12, the number of the swing arm 300 is at least two, including a first swing arm 310 and a second swing arm 320. The first swing arm 310 and the second swing arm 320 are respectively arranged on two sides of the base 900. The first swing arm 310 and the second swing arm 320 are respectively rotatably connected to the hinge bracket 100, that is, the hinge bracket 100 is provided with at least two arc-shaped sliding slots 120, and the arc-shaped sliding portion 301 of the first swing arm 310 and the arc-shaped sliding portion 301 of the second swing arm 320 are respectively in sliding fit with the two arc-shaped sliding slots 120.

The number of the extension portions is at least two, including a first extension portion 220 and a second extension portion 230. The first extension portion 220 and the second extension portion 230 are respectively arranged on two sides of the main body portion 210. The first extension portion 220 is opposite to the first swing arm 310, and the second extension portion 230 is opposite to the second swing arm 320. In some embodiments, the first extension portion 220 is opposite to the arc-shaped sliding portion 301 of the first swing arm 310, and the second extension portion 230 is opposite to the arc-shaped sliding portion 301 of the second swing arm 320. When the hinge mechanism is in the folded state, the arc-shaped sliding portion 301 of the first swing arm 310 abuts against the first extension portion 220, and the arc-shaped sliding portion 301 of the second swing arm 320 abuts against the second extension portion 230.

In some embodiments, as shown in FIG. 12, during the folding process of the hinge mechanism, the force applied by the display screen 700 to the hinge bracket 100 is F1, and the forces applied by the first swing arm 310 and the second swing arm 320 to the pressing member 200 are F2 and F3 respectively. F1, F2, and F3 are respectively parallel to a first direction A. The hinge bracket 100 is provided with a first surface 110 for contact of the display screen 700. The first direction A is perpendicular to a plane in which the first surface 110 is located. F2 and F3 are opposite to the direction of F1 respectively. Moreover, F2 +F3 =F1, so that the structure formed by the pressing member 200 and the hinge bracket 100 is in a force balance state.

By adopting this embodiment, the first swing arm 310 and the second swing arm 320 rotate relative to the hinge bracket 100 at the same time, which helps to improve the folding efficiency of the hinge mechanism. Based on this situation, the pressing member 200 is provided with extension portions corresponding to different swing arms 300 respectively, which helps to make different positions of the pressing member 200 abut against the first swing arm 310 and the second swing arm 320 respectively, helps to make the arc-shaped sliding portions 301 of the first swing arm 310 and the second swing arm 320 not prone to deformation, and ensures that the first swing arm 310 and the second swing arm 320 are not prone to misalignment. The rotation process of the first swing arm 310 and the second swing arm 320 is smoother, which helps to further improve the folding stability of the hinge mechanism.

In some embodiments, in the direction in which the rotation axis of the first swing arm 310 is located, at least two first protrusions 301a are arranged on the arc-shaped sliding portion 301 of the first swing arm 310 at intervals, at least two second protrusions 240 are arranged on the first extension portion 220 at intervals, and the first protrusions 301a are in one-to-one correspondence with the second protrusions 240. Similarly, in the direction in which the rotation axis of the second swing arm 320 is located, at least two first protrusions 301a are arranged on the arc-shaped sliding portion 301 of the second swing arm 320 at intervals, at least two second protrusions 240 are arranged on the second extension portion 230 at intervals, and the first protrusions 301a are in one-to-one correspondence with the second protrusions 240.

In some embodiments, the hinge bracket 100 is provided with a first surface 110 for contact of the display screen 700. During the folding process of the hinge mechanism, the display screen 700 deforms and acts on the first surface 110, and applies a force to the hinge bracket 100 through the first surface 110. Referring to FIG. 9, a surface of the main body portion 210 facing away from the hinge bracket 100 is provided with a clearance slot 211, and the clearance slot 211 is recessed relative to the first surface 110. The embodiments of the present application do not specifically limit the structure of the clearance slot 211.

By providing the clearance slot 211, during the folding process of the hinge mechanism, when the display screen 700 deforms, the portion at which the clearance slot 211 is provided will not apply force to the display screen 700, so as to prevent the display screen 700 from being damaged due to excessive stress.

In some embodiments, the surface of the main body portion 210 facing away from the hinge bracket 100 may not be provided with the clearance slot 211, that is, the portion structure is not recessed relative to the first surface 110.

In some embodiments, as shown in FIG. 9, an arc transition surface 213 is provided between the extension portion and the clearance slot 211, and the surface of the extension portion is smoothly connected to the clearance slot 211 through the arc transition surface 213. By adopting this embodiment, the arc transition surface 213 is used to realize a smooth connection between the extension portion and the clearance slot 211, so that the portion between the extension portion and the clearance slot 211 forms a smooth curved surface, so as to prevent the display screen 700 from being damaged by a protruding structure at the connection between the extension portion and the clearance slot 211 during the folding process.

In some embodiments, the main body portion 210 may be directly provided with the clearance slot 211, and no arc transition surface 213 needs to be provided between the clearance slot 211 and the extension portion.

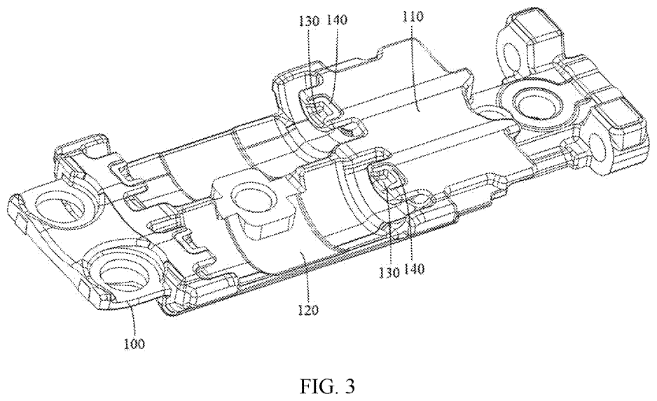

In some embodiments, the hinge bracket 100 is provided with a first welding structure, the extension portion is provided with a second welding structure, one of the first welding structure and the second welding structure is a welding slot 130, the other is a welding protrusion 250, and the welding protrusion 250 extends into the welding slot 130 so that the welding protrusion 250 is welded to the slot wall surface of the welding slot 130. In some embodiments, referring to FIG. 3 to FIG. 5, the hinge bracket 100 may be provided with the welding slot 130, and the welding slot 130 communicates with an installation slot for accommodating the pressing member 200. Referring to FIG. 9 and FIG. 10, the extension portion is provided with the welding protrusion 250. In some embodiments, the hinge bracket 100 is provided with the welding protrusion 250, and the extension portion is provided with the welding slot 130.

By adopting this embodiment, the welding slot 130 and the welding protrusion 250 are welded to each other, which helps to further position the extension portion, fix the position of the extension portion relative to the hinge bracket 100, and improve the connection stability between the pressing member 200 and the hinge bracket 100.

In some embodiments, two ends of the first extension portion 220 and two ends of the second extension portion 230 are provided with welding protrusions 250, the number of the welding slots 130 is plural, and the welding protrusions 250 are in one-to-one correspondence with the welding slots 130. In this way, a plurality of groups of cooperating welding protrusions 250 and welding slots 130 are used to weld and fix the ends of the respective extension portions of the pressing member 200 respectively, which helps to further position the pressing member 200.

In some embodiments, the extension portion and the hinge bracket 100 may not be provided with the welding protrusion 250 and the welding slot 130, that is, connected only through the main body portion 210 and the hinge bracket 100, and the extension portion is only configured to abut against the arc-shaped sliding portion 301.

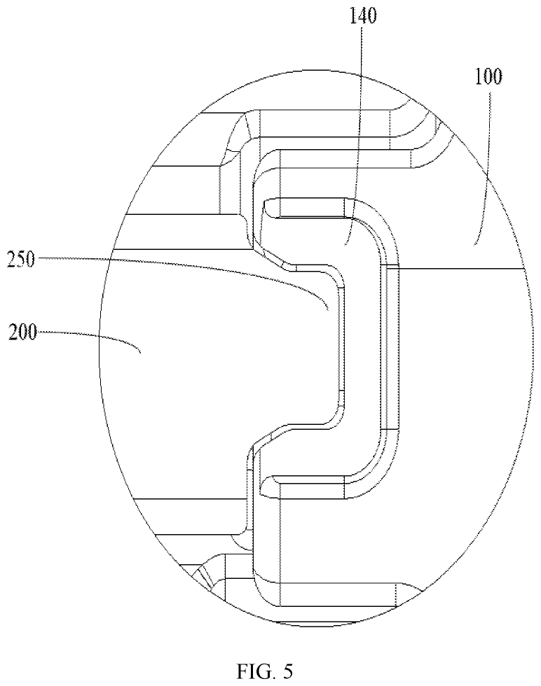

In some embodiments, referring to FIG. 3 and FIG. 5, the hinge bracket 100 or the extension portion is further provided with a slag accommodating slot 140, the slag accommodating slot 140 communicates with the welding slot 130, and the welding slot 130 is formed in a bottom wall surface of the slag accommodating slot 140. The embodiments of the present application do not limit the specific structure of the slag accommodating slot 140, as long as a total area of its bottom wall surface is greater than an opening area of the welding slot 130.

By adopting this embodiment, the slag accommodating slot 140 can accommodate the welding slag generated during the welding process of the welding slot 130 and the welding protrusion 250, so as to prevent the welding slag from directly protruding from the surface of the hinge bracket 100 or the extension portion to damage the display screen 700, thereby improving the safety performance of the display screen 700.

In some embodiments, the hinge bracket 100 or the extension portion may not be provided with the slag accommodating slot 140, that is, the welding slag directly falls on the surface of the hinge bracket 100 or the extension portion.

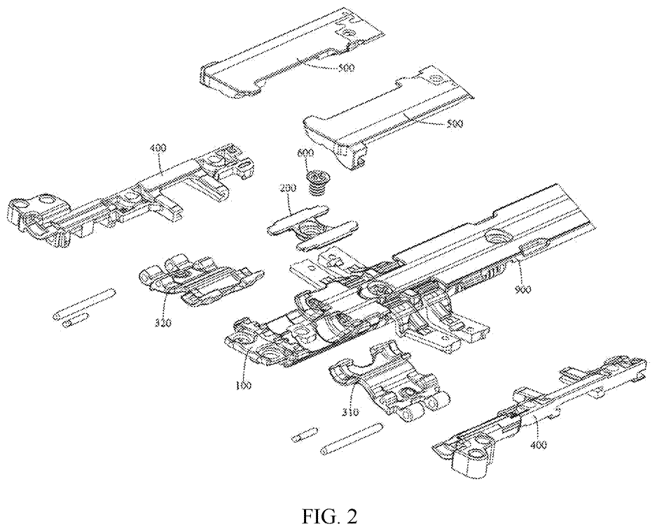

In some embodiments, referring to FIG. 1 and FIG. 2, the hinge mechanism further includes a frame connection member 400 and a connection plate 500. The frame connection member 400 is rotatably connected to the swing arm 300, and the frame connection member 400 drives the swing arm 300 to rotate relative to the base 900. The connection plate 500 is opposite to the frame connection member 400 and the swing arm 300. The connection plate 500 is configured to shield the frame connection member 400 and the swing arm 300 to improve the appearance performance. A surface of the connection plate 500 is located in the same plane as a surface of the base 900. In some embodiments, the frame connection member 400 and the connection plate 500 are provided on both sides of the base 900.

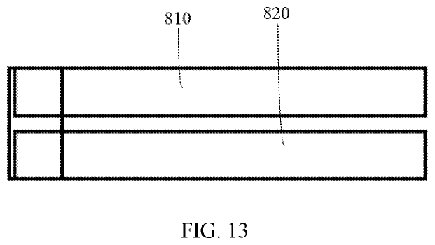

Based on the hinge mechanism disclosed in the present application, referring to FIG. 13, an embodiment of the present application further provides an electronic device. The electronic device includes a first device body 810, a second device body 820, and the hinge mechanism in the above embodiments. The first device body 810 is connected to the second device body 820 through the hinge mechanism. During the relative rotation of the first device body 810 and the second device body 820, the electronic device switches between an unfolded state and a folded state. In this way, during the folding process of the electronic device, the overall structure formed by the hinge bracket 100 and the pressing member 200 is in a relatively balanced state, the arc-shaped sliding portion 301 is not prone to deformation, the swing arm 300 is not prone to misalignment, and the rotation process of the swing arm 300 is smoother, which helps to improve the folding stability.

The embodiments of the present application have been described above with reference to the accompanying drawings, but the present application is not limited to the specific embodiments described above. The specific embodiments described above are only illustrative and not restrictive. Those of ordinary skill in the art can make many forms under the teaching of the present application without departing from the spirit of the present application and scope protected by the claims, all of which fall within the scope of protection of the present application.

What is claimed is:

1. A hinge mechanism, comprising:
a base;
a hinge bracket provided on the base, wherein the hinge bracket is provided with an arc-shaped sliding slot;
a swing arm, wherein the swing arm is provided with an arc-shaped sliding portion, and the arc-shaped sliding portion is in sliding fit with the arc-shaped sliding slot; and
a pressing member, wherein the pressing member is located on a side of the arc-shaped sliding portion facing away from the hinge bracket, and the pressing member is connected to the hinge bracket.

2. The hinge mechanism according to claim 1, wherein:
a first protrusion is provided on a side of the arc-shaped sliding portion facing the pressing member, and a second protrusion is provided on a side of the pressing member facing the arc-shaped sliding portion; and
when the hinge mechanism is in a folded state, the first protrusion abuts against the second protrusion.

3. The hinge mechanism according to claim 2, wherein at least one of the first protrusion or the second protrusion extends along a direction in which a rotation axis of the swing arm is located.

4. The hinge mechanism according to claim 2, wherein in the direction in which the rotation axis of the swing arm is located, at least two of the first protrusions are arranged on the swing arm at intervals, at least two of the second protrusions are arranged on the pressing member at intervals, and the first protrusions are in one-to-one correspondence with the second protrusions.

5. The hinge mechanism according to claim 1, wherein:
the pressing member comprises a main body portion and an extension portion that are connected to each other,
wherein the main body portion is detachably connected to the hinge bracket through a fastener, and
when the hinge mechanism is in a folded state, the extension portion abuts against the arc-shaped sliding portion.

6. The hinge mechanism according to claim 5, wherein:
the number of the swing arm is at least two, the at least two swing arms comprise a first swing arm and a second swing arm, wherein the first swing arm and the second swing arm are respectively provided on two sides of the base;
the number of the extension portion is at least two, the at least two extension portions comprise a first extension portion and a second extension portion, wherein the first extension portion and the second extension portion are respectively provided on two sides of the main body portion, the first extension portion is opposite to the first swing arm, the second extension portion is opposite to the second swing arm; and
when the hinge mechanism is in the folded state, the arc-shaped sliding portion of the first swing arm abuts against the first extension portion, and the arc-shaped sliding portion of the second swing arm abuts against the second extension portion.

7. The hinge mechanism according to claim 5, wherein:
the hinge bracket is provided with a first surface for contact with a display screen,
a surface of the main body portion facing away from the hinge bracket is provided with a clearance slot, and
the clearance slot is recessed relative to the first surface.

8. The hinge mechanism according to claim 7, wherein an arc transition surface is provided between the extension portion and the clearance slot, and the surface of the extension portion is smoothly connected to the clearance slot through the arc transition surface.

9. The hinge mechanism according to claim 5, wherein:
the hinge bracket is provided with a first welding structure,
the extension portion is provided with a second welding structure,
one of the first welding structure and the second welding structure is a welding slot, and the other is a welding protrusion, and
the welding protrusion extends into the welding slot so that the welding protrusion is welded to the slot wall surface of the welding slot.

10. The hinge mechanism according to claim 9, wherein:
the hinge bracket or the extension portion is further provided with a slag accommodating slot,
the slag accommodating slot communicates with the welding slot, and
the welding slot is formed in a bottom wall surface of the slag accommodating slot.

11. An electronic device, comprising a first device body, a second device body, and a hinge mechanism, wherein the hinge mechanism comprises:
a base;
a hinge bracket provided on the base, wherein the hinge bracket is provided with an arc-shaped sliding slot;
a swing arm, wherein the swing arm is provided with an arc-shaped sliding portion, and the arc-shaped sliding portion is in sliding fit with the arc-shaped sliding slot; and
a pressing member, wherein the pressing member is located on a side of the arc-shaped sliding portion facing away from the hinge bracket, and the pressing member is connected to the hinge bracket,
wherein the first device body is connected to the second device body through the hinge mechanism; and
during a relative rotation of the first device body and the second device body, the electronic device switches between an unfolded state and a folded state.

12. The electronic device according to claim 11, wherein in the hinge mechanism:
a first protrusion is provided on a side of the arc-shaped sliding portion facing the pressing member, and a second protrusion is provided on a side of the pressing member facing the arc-shaped sliding portion; and
when the hinge mechanism is in a folded state, the first protrusion abuts against the second protrusion.

13. The electronic device according to claim 12, wherein in the hinge mechanism:
at least one of the first protrusion or the second protrusion extends along a direction in which a rotation axis of the swing arm is located.

14. The electronic device according to claim 12, wherein in the hinge mechanism:
in the direction in which the rotation axis of the swing arm is located, at least two of the first protrusions are arranged on the swing arm at intervals, at least two of the second protrusions are arranged on the pressing member at intervals, and the first protrusions are in one-to-one correspondence with the second protrusions.

15. The electronic device according to claim 11, wherein in the hinge mechanism:
the pressing member comprises a main body portion and an extension portion that are connected to each other,
wherein the main body portion is detachably connected to the hinge bracket through a fastener, and
when the hinge mechanism is in a folded state, the extension portion abuts against the arc-shaped sliding portion.

16. The electronic device according to claim 15, wherein in the hinge mechanism:
the number of the swing arm is at least two, the at least two swing arms comprise a first swing arm and a second swing arm, wherein the first swing arm and the second swing arm are respectively provided on two sides of the base;
the number of the extension portion is at least two, the at least two extension portions comprise a first extension portion and a second extension portion, wherein the first extension portion and the second extension portion are respectively provided on two sides of the main body portion, the first extension portion is opposite to the first swing arm, the second extension portion is opposite to the second swing arm; and
when the hinge mechanism is in the folded state, the arc-shaped sliding portion of the first swing arm abuts against the first extension portion, and the arc-shaped sliding portion of the second swing arm abuts against the second extension portion.

17. The electronic device according to claim 15, wherein in the hinge mechanism:
the hinge bracket is provided with a first surface for contact with a display screen,
a surface of the main body portion facing away from the hinge bracket is provided with a clearance slot, and
the clearance slot is recessed relative to the first surface.

18. The electronic device according to claim 17, wherein in the hinge mechanism, an arc transition surface is provided between the extension portion and the clearance slot, and the surface of the extension portion is smoothly connected to the clearance slot through the arc transition surface.

19. The electronic device according to claim 15, wherein in the hinge mechanism:
the hinge bracket is provided with a first welding structure,
the extension portion is provided with a second welding structure,
one of the first welding structure and the second welding structure is a welding slot, and the other is a welding protrusion, and
the welding protrusion extends into the welding slot so that the welding protrusion is welded to the slot wall surface of the welding slot.

20. The electronic device according to claim 19, wherein in the hinge mechanism:
the hinge bracket or the extension portion is further provided with a slag accommodating slot,
the slag accommodating slot communicates with the welding slot, and
the welding slot is formed in a bottom wall surface of the slag accommodating slot.
